(19) United States
(12) Patent Application Publication
(10) Pub. No.: US 2024/0423058 A1
(43) Pub. Date: Dec. 19, 2024

(54) DISPLAY DEVICE AND METHOD OF MANUFACTURING A SAME

(71) Applicant: Samsung Display Co., LTD., Yongin-si (KR)

(72) Inventors: Young Min KIM, Yongin-si (KR); Rae Young KIM, Yongin-si (KR); Hyun Seok KIM, Yongin-si (KR); Hyeong Gyu KIM, Yongin-si (KR); Hyo Joon KIM, Yongin-si (KR); Hyun Woo NOH, Yongin-si (KR); Keun Young PARK, Yongin-si (KR); Moon Jung BAEK, Yongin-si (KR); Hye Seung LEE, Yongin-si (KR)

(21) Appl. No.: 18/406,138

(22) Filed: Jan. 6, 2024

(30) Foreign Application Priority Data
Jun. 15, 2023 (KR) 10-2023-0077028

(51) Int. Cl. H10K 59/38; H10K 59/122; H10K 59/35; H10K 71/00

(52) U.S. Cl. CPC H10K 59/38; H10K 59/122; H10K 59/353; H10K 71/00

(57) ABSTRACT

A display device includes a first substrate, on which first to third sub-pixel areas spaced apart from each other and a non-emission area corresponding to a boundary of the first to third sub-pixel areas are defined, a display element layer including a light emitting element disposed in each of the first to third sub-pixel areas on the first substrate, and a color-filter layer disposed on the display element layer. The color-filter layer includes a base layer, a first color filter disposed on the base layer and corresponding to the first sub-pixel area, a second color filter disposed on the base layer and corresponding to the second sub-pixel area, a first planarization layer covering the first color filter and the second color filter, a third color filter disposed on the first planarization layer and corresponding to the third sub-pixel area, and a second planarization layer covering the third color filter.

This application claims priority to Korean patent application No. 10-2023-0077028, filed on Jun. 15, 2023, and all the benefits accruing therefrom under 35 U.S.C. § 119, the content of which in its entirety is herein incorporated by reference.

### BACKGROUND

### 1. Field

The disclosure relates to a display device and a method of manufacturing the display device.

### 2. Description of the Related Art

A flat panel display device is used as a display device replacing a cathode ray tube display device due to desired characteristics thereof, such as light weight, thin shape, and the like. A representative example of such a flat panel display includes a liquid crystal display device and an organic light emitting display device.

A display device may include a light emitting element that generates light, a color conversion unit that converts a wavelength of the light generated by the light emitting element, and a color-filter layer disposed on the color conversion unit. The color-filter layer may include a plurality of color-filter layers that selectively transmits light of different colors.

### SUMMARY

In an embodiments of the disclosure is directed to a display device with improved visibility by disposing a color filter disposed at an outermost periphery of a color-filter layer on a protective layer covering a remaining color-filter layer to improve planarization of the color filter disposed at the outermost periphery and securing a thickness of the color filter disposed at the outermost periphery, thereby improving diffusion reflection of external light incident on a display device.

According to embodiments of the disclosure, a display device includes a first substrate, on which first to third sub-pixel areas spaced apart from each other and a non-emission area corresponding to a boundary of the first to third sub-pixel areas are defined, a display element layer including a light emitting element disposed in each of the first to third sub-pixel areas on the first substrate, and a color-filter layer disposed on the display element layer, where the color-filter layer includes a base layer, a first color filter disposed on the base layer and corresponding to the first sub-pixel area, a second color filter disposed on the base layer and corresponding to the second sub-pixel area, a first planarization layer covering the first color filter and the second color filter, a third color filter disposed on the first planarization layer and corresponding to the third sub-pixel area, and a second planarization layer covering the third color filter.

According to an embodiment, the first planarization layer may directly contact a portion of the base layer corresponding to the third sub-pixel area.

According to an embodiment, the first and second color filters may be disposed in a same layer as each other, and the third color filter may be disposed in a layer different from a layer in which the first and second color filters are disposed, with the first planarization layer interposed therebetween.

According to an embodiment, a portion of the second color filter overlapping the non-emission area may be at least partially covered by a portion of the first color filter overlapping the non-emission area.

According to an embodiment, a portion of the second color filter overlapping the non-emission area may cover at least a portion of the first color filter overlapping the non-emission area.

According to an embodiment, a portion of each of the first to third color filters may be disposed in the non-emission area, and the portion of each of the first to third color filters disposed in the non-emission area may be sequentially stacked in a third direction.

According to an embodiment, a portion of the first color filter and a portion of the second color filter, each overlapping the non-emission area, may overlap a portion of the third color filter disposed in the non-emission area in a plan view.

According to an embodiment, the first to third color filters may be disposed in the non-emission area, and the first color filter and the second color filter disposed in the non-emission area may not overlap each other in a plan view.

According to an embodiment, the third color filter may have a constant thickness over the third sub-pixel area and the non-emission area.

According to an embodiment, the display device may further include an encapsulation layer disposed on the display element layer, and a light-conversion layer disposed between the encapsulation layer and the color-filter layer.

According to an embodiment, the light-conversion layer may include a bank disposed in the boundary of the first to third sub-pixel areas and defining a first opening, and a color conversion layer disposed in the first opening of the bank.

According to an embodiment, the light-conversion layer may further include a first capping layer covering the bank and the light-conversion layer, and a low refractive layer disposed on the first capping layer.

According to an embodiment, the display element layer may include first pixel electrodes disposed in the first to third sub-pixel areas on the substrate, a pixel defining layer disposed on the first pixel electrodes, where second openings are defined through the pixel defining layer to expose the first pixel electrodes, an organic light emitting unit disposed on the first pixel electrodes, and a second pixel electrode disposed on the organic light emitting unit.

According to an embodiment, the third color filter may not contact the first and second color filters.

According to embodiments of the disclosure, a method of manufacturing a display device includes preparing a first substrate on which first to third sub-pixel areas and a non-emission area corresponding to a boundary of the first to third sub-pixel areas are defined, forming a base layer on the first substrate, forming a second color filter corresponding to the second sub-pixel area on the base layer, forming a first color filter corresponding to the first sub-pixel area on the base layer, forming a first planarization layer covering the first color filter and the second color filter on the base layer, forming a third color filter corresponding to the third sub-pixel area on the first planarization layer, and forming a second planarization layer covering the third color filter on the first planarization layer.

According to an embodiment, the method may further include forming a display element layer including a light emitting element disposed in each of the first to third sub-pixel areas between the first substrate and the base layer.

According to an embodiment, the forming the first color filter may include forming the first color filter to extend from the first sub-pixel area to the non-emission area, and the forming the second color filter may include forming the second color filter to extend from the second sub-pixel area to the non-emission area.

According to an embodiment, a portion of the first color filter overlapping the non-emission area may cover a portion of the second color filter overlapping the non-emission area.

According to an embodiment, a portion of the second color filter overlapping the non-emission area may cover a portion of the first color filter overlapping the non-emission area.

According to an embodiment, the forming the first planarization layer may include filling the third sub-pixel area on the base layer.

According to an embodiment, the forming the third color filter may include forming the third color filter at a constant thickness from the third sub-pixel area to the non-emission area.

A display device according to embodiments of the disclosure the display device has a flat surface with a predetermined constant thickness by disposing one of color filters on a first planarization layer which is a layer distinguished from a remaining color filter such that deterioration in visibility due to reflected light (or diffusion reflection) when external light is incident to a non-emission area of a color-filter layer may be substantially reduced or effectively prevented.

However, an effect of the disclosure is not limited to the above-described effects, and may be variously expanded without departing from the spirit and scope of the disclosure.

### BRIEF DESCRIPTION OF THE DRAWINGS

The above and other features of the disclosure will become more apparent by describing in further detail embodiments thereof with reference to the accompanying drawings, in which:

FIG. 1 is a schematic plan view illustrating a display device according to embodiments of the disclosure;

FIGS. 2A to 2C are plan views illustrating embodiments of a pixel of FIG. 1;

FIG. 3 is a schematic cross-sectional view illustrating an embodiment of a display panel of FIG. 1;

FIG. 4 is a circuit diagram illustrating an embodiment of a sub-pixel included in the pixel of FIGS. 2A to 2C;

FIG. 5A is a cross-sectional view illustrating an embodiment of a light emitting element of FIG. 4;

FIG. 5B is a cross-sectional view illustrating an alternative embodiment of the light emitting element of FIG. 4;

FIG. 6 is a cross-sectional view illustrating an embodiment of the pixel including the light emitting element of FIG. 5A or 5B;

FIG. 7A is a cross-sectional view illustrating a comparative example of a color-filter layer of sub-pixels included in the pixel of FIG. 6;

FIG. 7B is a cross-sectional view illustrating an embodiment of a color-filter layer of the sub-pixels included in the pixel of FIG. 6;

FIG. 8 is a cross-sectional view illustrating an alternative embodiment of the pixel including the light emitting element of FIG. 5A or 5B;

FIG. 9 is a cross-sectional view illustrating another alternative embodiment of the pixel including the light emitting element of FIG. 5A or 5B; and

FIGS. 10 to 15 are cross-sectional views illustrating a method of manufacturing a display device according to embodiments of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in greater detail with reference to the accompanying drawings. A same reference numerals are used for a same components in the drawings, and any repetitive detailed description of the same components may be omitted or simplified.

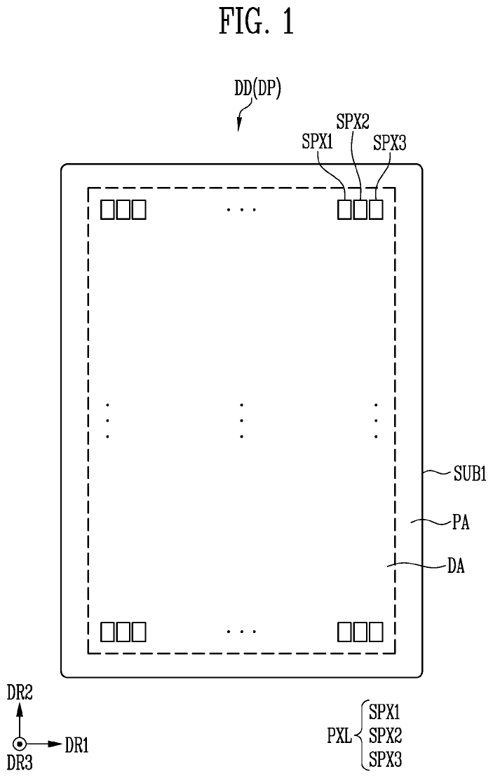

FIG. 1 is a schematic plan view illustrating a display device according to embodiments of the disclosure.

Referring to FIG. 1, a display panel DP (or a display device DD) according to an embodiment may be provided in various shapes in a plan view, for example, a rectangular plate shape having two pairs of sides parallel to each other, but is not limited thereto. In an embodiment where the display panel DP is in a rectangular plate shape, one pair of sides of the two pairs of sides may be provided longer than the other pair of sides.

At least a portion of the display panel DP may have flexibility and may be folded (or foldable) at a portion having flexibility, but is not limited thereto.

The display panel DP may display an image. As the display panel DP, a display panel capable of self-emission such as an organic light emitting display panel (OLED panel) using an organic light emitting diode as a light emitting element, an ultra-small light emitting diode display panel (micro-LED or nano-LED display panel) using an ultra-small light emitting diode as a light emitting element, and a quantum dot organic light emitting display panel (QD OLED panel) using a quantum dot and an organic light emitting diode may be used. In addition, as the display panel DP, a non-emission display panel such as a liquid crystal display panel (LCD panel), an electro-phoretic display panel (EPD panel), and an electro-wetting display panel (EWD panel) may be used. In an embodiment where the non-emission display panel is used as the display panel DP, the display device DD may include a backlight unit for supplying light to the display panel DP.

The display panel DP may include a first substrate SUB1 and pixels PXL provided (disposed or formed) on the first substrate SUB1.

The first substrate SUB1 may include a transparent insulating material to transmit light. The first substrate SUB1 may be a rigid substrate or a flexible substrate. The rigid substrate may be, for example, one of a glass substrate, a quartz substrate, a glass ceramic substrate, and a crystalline glass substrate.

The flexible substrate may be one of a film substrate and a plastic substrate including a polymeric organic material. In an embodiment, for example, the flexible substrate may include at least one selected from polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, triacetate cellulose, and cellulose acetate propionate.

The display device DD may have one of various shapes. In an embodiment, for example, the display device DD may be provided in a rectangular shape, but is not limited thereto. In an alternative embodiment, for example, the display device DD may have a circular or elliptical shape. In addition, the display device DD may include an angled corner and/or a curved corner. For convenience of illustration, in FIG. 1, an embodiment where the display device DD has a rectangular plate shape is shown. In addition, in FIG. 1, an extension direction of a short side of the display device DD (for example, a horizontal direction) is indicated as a first direction DR1, and an extension direction of a long side (for example, a vertical direction) is indicated as a second direction DR2. In FIG. 1, a third direction DR3, which is perpendicular to the first direction DR1 and the second direction DR2, may be a thickness direction of the display device DD or the display panel DP.

The first substrate SUB1 (and the display device DD) may include a display area DA for displaying an image and a peripheral area PA (or a non-display area) excluding the display area DA. The first substrate SUB1 may include the display area DA including pixel areas where each pixel PXL is disposed and a peripheral area PA disposed around (or adjacent to) the display area DA.

The peripheral area PA may be positioned adjacent to the display area DA. The peripheral area PA may be adjacent to at least one side of the display area DA. In an embodiment, for example, the peripheral area PA may surround a circumference (or an edge) of the display area DA. In an embodiment, for example, the peripheral area PA may be a bezel area of the display device DD.

A pixel PXL may be disposed in the display area DA on the first substrate SUB1. The peripheral area PA may be disposed around the display area DA. The peripheral area PA may have a structure for protecting a configuration included in the pixels PXL disposed in the display area DA, but is not limited thereto. In an embodiment, for example, a line unit connected to each pixel PXL and a driver connected to the line unit for driving the pixel PXL may be provided in the peripheral area PA.

The pixel PXL may include a plurality of pixels SPX1 to SPX3. In an embodiment, for example, the pixel PXL may include a first sub-pixel SPX1, a second sub-pixel SPX2, and a third sub-pixel SPX3. The first sub-pixel SPX1, the second sub-pixel SPX2, and the third sub-pixel SPX3 may be sequentially disposed in the first direction DR1. However, the disclosure is not limited thereto, and alternatively, the first sub-pixel SPX1, the second sub-pixel SPX2, and the third sub-pixel SPX3 may be sequentially disposed in the second direction DR2 crossing the first direction DR1.

The first to third sub-pixels SPX1 to SPX3 may emit light in different colors. In an embodiment, for example, the first sub-pixel SPX1 may be a red sub-pixel that emits red light, the second sub-pixel SPX2 may be a green sub-pixel that emits green light, and the third sub-pixel SPX3 may be a blue sub-pixel that emits blue light. However, a color, a type, the number, and/or the like of the pixels configuring the pixel PXL are/is not particularly limited. In an embodiment, for example, colors of the light emitted from each of the first to third sub-pixels SPX1 to SPX3 may be variously changed. Hereinafter, the first to third sub-pixels SPX1 to SPX3 may be collectively referred to as a pixel PXL.

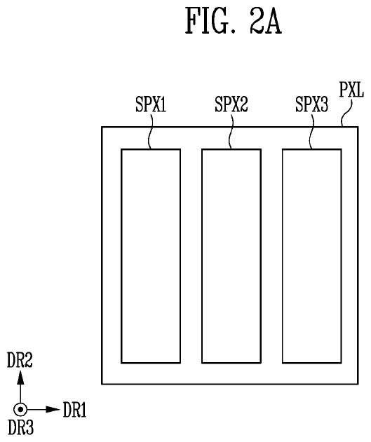

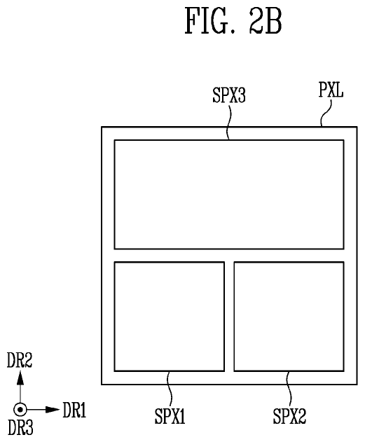

FIGS. 2A to 2C are plan views illustrating embodiments of the pixel of FIG. 1.

Referring to FIGS. 1 and 2A to 2C, an embodiment of the pixel PXL may include the plurality of sub-pixels SPX1 to SPX3. FIGS. 2A to 2C illustrate embodiments where each pixel PXL includes the first sub-pixel SPX1, the second sub-pixel SPX2, and the third sub-pixel SPX3, but an embodiment of the disclosure is not limited.

Each of the first sub-pixel SPX1, the second sub-pixel SPX2, and the third sub-pixel SPX3 may be connected to one corresponding data line among data lines and at least one corresponding scan line among scan lines.

Referring to FIGS. 2A to 2C, each of the first sub-pixel SPX1, the second sub-pixel SPX2, and the third sub-pixel SPX3 may have a rectangular, square, or polygonal planar shape.

Referring to FIG. 2A, in an embodiment, each of the first sub-pixel SPX1, the second sub-pixel SPX2, and the third sub-pixel SPX3 may have a rectangular planar shape having a short side extending in the first direction DR1 and a long side extending in the second direction DR2. However, the disclosure is not limited thereto, and according to an alternative embodiment, each of the first sub-pixel SPX1, the second sub-pixel SPX2, and the third sub-pixel SPX3 may have a plane shape of a square or rhombus including sides having a same length in the first direction DR1 and the second direction DR2. In an embodiment, for example, the first sub-pixel SPX1, the second sub-pixel SPX2, and the third sub-pixel SPX3 may be arranged in the first direction DR1. In an embodiment, for example, areas of the first to third sub-pixels SPX1 to SPX3 may have substantially the same as each other, but are not limited thereto. In an alternative embodiment, for example, at least one of the areas of the first to third sub-pixels SPX1 to SPX3 may be different from another one. Alternatively, any two of the area of the first sub-pixel SPX1, the area of the second sub-pixel SPX2, and the area of the third sub-pixel SPX3 may be substantially the same as each other, and the other may be different from the two. Alternatively, the area of the first sub-pixel SPX1, the area of the second sub-pixel SPX2, and the area of the third sub-pixel SPX3 may be different from each other.

Referring to FIG. 2B, in an alternative embodiment, the first sub-pixel SPX1 may be arranged with any one of the second sub-pixel SPX2 and the third sub-pixel SPX3 in the first direction DR1 and may be arranged with the other one in the second direction DR2. In an embodiment, for example, the first sub-pixel SPX1 may be arranged with the second sub-pixel SPX2 side by side in the first direction DR1, and the first sub-pixel SPX1 may be arranged with the third sub-pixel SPX3 in the second direction. DR2. In an embodiment, for example, the third sub-pixel SPX3 may be disposed in the second direction DR2 of the first sub-pixel SPX1 and the second sub-pixel SPX2. In an embodiment, for example, the areas of the first and second sub-pixels SPX1 and SPX2 may be substantially equal to each other, and the area of the third sub-pixel SPX3 may be different from the areas of the first and second sub-pixels SPX1 and SPX2. In an embodiment, for example, the area of the third sub-pixel SPX3 may be greater than the areas of the first and second sub-pixels SPX1 and SPX2.

Referring to FIG. 2C, in an alternative embodiment, each of the first sub-pixel SPX1, the second sub-pixel SPX2, and the third sub-pixel SPX3 may have a hexagonal or regular hexagonal planar shape. In an embodiment, for example, two adjacent surfaces of six surfaces of each of the first to third sub-pixels SPX1 to SPX3 may face one surface of adjacent sub-pixels.

Referring to FIGS. 2A to 2C, in an embodiment, the first sub-pixel SPX1 may emit first light, the second sub-pixel SPX2 may emit second light, and the third sub-pixel SPX3 may emit third light. The first light may be light of a red wavelength band, the second light may be light of a green wavelength band, and the third light may be light of a blue wavelength band. The red wavelength band may be a wavelength band of about 600 nanometers (nm) to about 750 nm, the green wavelength band may be a wavelength band of about 480 nm to about 560 nm, and the blue wavelength band may be a wavelength band of about 370 nm to about 460 nm, but an embodiment of the present specification is not limited thereto.

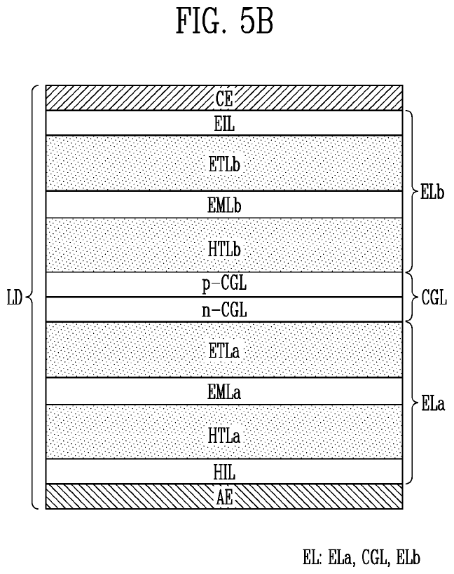

Each of the first sub-pixel SPX1, the second sub-pixel SPX2, and the third sub-pixel SPX3 may include a light emitting element that emits light (for example, a light emitting element LD of FIG. 5A or 5B), and the light emitting element may include an organic light emitting element including an organic layer.

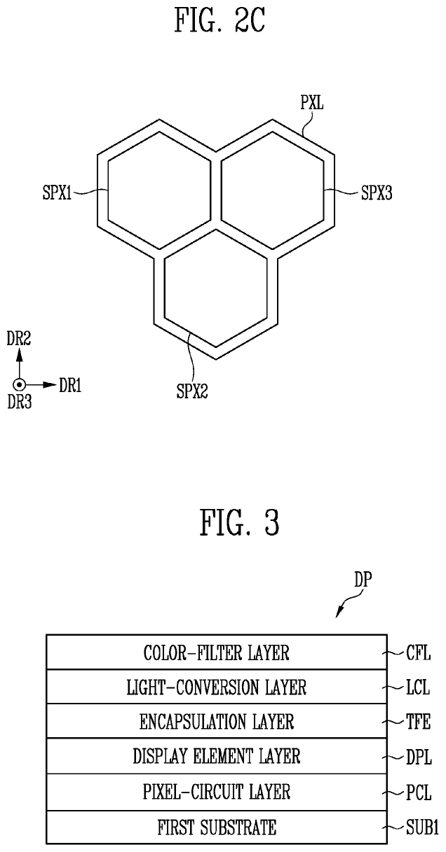

FIG. 3 is a schematic cross-sectional view illustrating an embodiment of the display panel of FIG. 1.

Referring to FIG. 3, an embodiment of the display panel DP may include a first substrate SUB1, a pixel-circuit layer PCL, a display element layer DPL, an encapsulation layer TFE, a light-conversion layer LCL, and a color-filter layer CFL. In an embodiment, for example, the first substrate SUB1, the pixel-circuit layer PCL, the display element layer DPL, the encapsulation layer TFE, the light-conversion layer LCL, and the color-filter layer CFL may be sequentially stacked one on another in the third direction DR3.

The pixel-circuit layer PCL may be disposed on the first substrate SUB1 and may include a plurality of transistors and signal lines connected to the transistors. In an embodiment, for example, each transistor may have a form in which a semiconductor pattern, a gate electrode, a source electrode, and a drain electrode are sequentially stacked with an insulating layer interposed therebetween. The semiconductor pattern may include amorphous silicon, poly silicon, low temperature poly silicon, an organic semiconductor, and/or an oxide semiconductor. The gate electrode, the source electrode, and the drain electrode may include at least one selected from aluminum (Al), copper (Cu), titanium (Ti), and molybdenum (Mo), but are not limited thereto. In addition, the pixel-circuit layer PCL may include one or more insulating layers.

The display element layer DPL may be disposed on the pixel-circuit layer PCL. The display element layer DPL may include the light emitting element that emits light (for example, the light emitting element LD of FIG. 5A or 5B). The light emitting element may be, for example, an organic light emitting diode, but is not limited thereto. According to an embodiment, the light emitting element may be an inorganic light emitting element including an inorganic light emitting material or a light emitting element that emits light by changing a wavelength of emitted light using a quantum dot.

The encapsulation layer TFE may be disposed on the display element layer DPL. The encapsulation layer TFE may be an encapsulation substrate or have a form of an encapsulation film formed of (or defined by) a multilayer film. In an embodiment where the encapsulation layer TFE is in the form of the encapsulation film, the encapsulation layer TFE may include an inorganic layer and/or an organic layer. In an embodiment, for example, the encapsulation layer TFE may have a form in which an inorganic layer, an organic layer, and an inorganic layer are sequentially stacked. The encapsulation layer TFE may effectively prevent penetration of external air and moisture into the display element layer DPL and the pixel-circuit layer PCL.

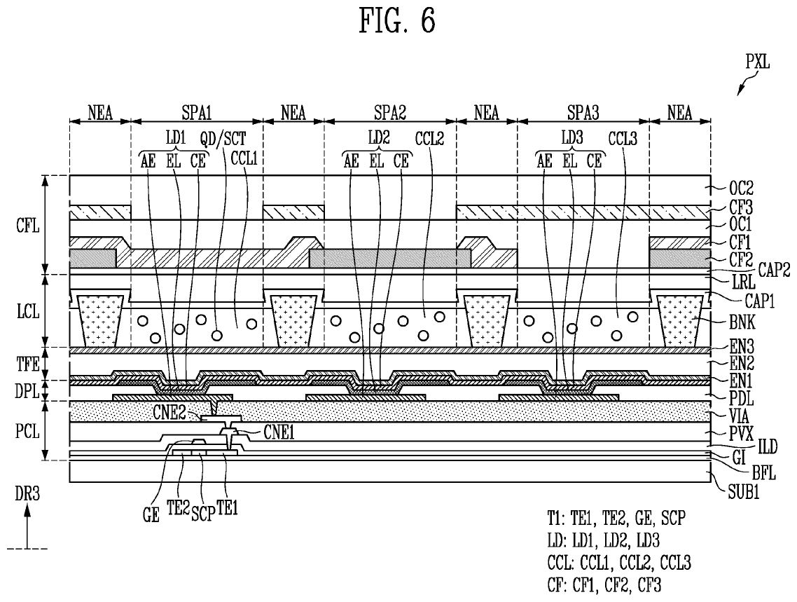

The light-conversion layer LCL may be disposed on the encapsulation layer TFE. The light-conversion layer LCPL may include elements for converting light emitted from the display element layer DPL into light of a specific color to increase light emission efficiency. In an example, the light-conversion layer LCL may include a color conversion layer (for example, a color conversion layer CCL of FIG. 6) and a low refractive layer (for example, a low refractive layer LRL of FIG. 6).

The color-filter layer CFL may be disposed on the light-conversion layer LCL. The color-filter layer CFL may selectively transmit light passing through the light-conversion layer LCL (or the display element layer DPL). The color-filter layer CFL may include first to third color filters (for example, first to third color filters CF1 to CF3 of FIG. 6).

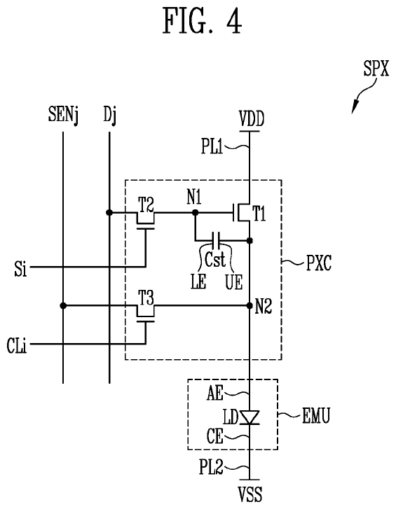

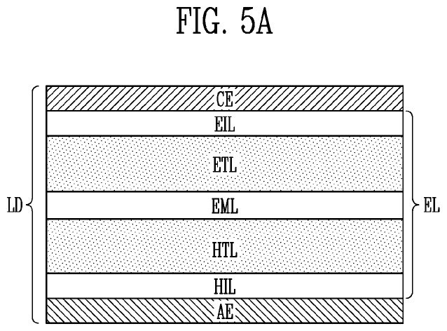

FIG. 4 is a circuit diagram illustrating an embodiment of the sub-pixel included in the pixel of FIGS. 2A to 2C.

The sub-pixel SPX shown in FIG. 4 may be any one of the sub-pixels SPX1 to SPX3 shown in FIG. 1, and the sub-pixels SPX1 to SPX3 arranged in the display area of the display device DD may be configured substantially identically or similarly to each other.

In FIG. 4, for convenience, a sub-pixel SPX positioned in an i-th pixel row (or an i-th horizontal line) and a j-th pixel column is shown (where i and j are natural numbers).

Referring to FIG. 4, an embodiment of the sub-pixel SPX may include a light emitting unit EMU that generates light of a luminance corresponding to a data signal. In addition, the sub-pixel SPX may further include a pixel circuit PXC for driving the light emitting unit EMU.

The light emitting unit EMU may include a light emitting element LD connected between a first power line PL1 that receives a voltage of first driving power VDD (or a first power voltage) and a second power line PL2 that receives a voltage of second driving power VSS (or a second power voltage). In an embodiment, for example, the light emitting unit EMU may include the light emitting element LD including a first pixel electrode AE connected to the first driving power VDD via the pixel circuit PXC and the first power line PL1 and a second pixel electrode CE connected to the second driving power VSS via the second power line PL2. The first pixel electrode AE may be an anode, and the second pixel electrode CE may be a cathode. The first driving power VDD and the second driving power VSS may have different potentials or voltage levels from each other. In such an embodiment, a potential difference between the first driving power VDD and the second driving power VSS may be set to be higher than or equal to a threshold voltage of the light emitting element LD during an emission period of the sub-pixel SPX.

In such an embodiment where the sub-pixel SPX is positioned in the i-th pixel row and the j-th pixel column in the display area DA, the pixel circuit PXC of the sub-pixel SPX (or the sub-pixel) may be electrically connected to an i-th scan line Si and a j-th data line Dj. In addition, the pixel circuit PXC may be electrically connected to an i-th control line CLi and a j-th sensing line SENj.

In an embodiment, as shown in FIG. 4, the pixel circuit PXC may include first to third transistors T1 to T3 and a storage capacitor Cst.

The first transistor T1 may be a driving transistor for controlling a driving current applied to the light emitting element LD, and may be electrically connected between the first driving power VDD and the light emitting element LD. Specifically, a first terminal of the first transistor T1 may be electrically connected to the first driving power VDD through the first power line PL1, a second terminal of the first transistor T1 may be electrically connected to a second node N2, and a gate electrode of the first transistor T1 may be electrically connected to a first node N1. The first transistor T1 may control an amount of the driving current applied from the first driving power VDD to the light emitting element LD through the second node N2 based on a voltage applied to the first node N1. In an embodiment, the first terminal of the first transistor T1 may be a drain electrode, and the second terminal of the first transistor T1 may be a source electrode, but the disclosure is not limited thereto. According to an embodiment, the first terminal may be a source electrode and the second terminal may be a drain electrode.

The second transistor T2 may be a switching transistor that selects the sub-pixel SPX in response to a scan signal and activates the sub-pixel SPX, and may be electrically connected between the data line Dj (for example, the j-th data line) and the first node N1. A first terminal of the second transistor T2 may be electrically connected to the data line Dj, a second terminal of the second transistor T2 may be connected to the first node N1 (or the gate electrode of the first transistor T1), and a gate electrode of the second transistor T2 may be electrically connected to the scan line Si (or the i-th scan line). The first terminal and the second terminal of the second transistor T2 may be different terminals, and for example, the first terminal may be a drain electrode and a second terminal may be a source electrode.

The second transistor T2 may be turned on when a scan signal of a gate-on voltage (for example, a high level voltage) is supplied from the scan line Si, to electrically connect the data line Dj and the first node N1 to each other. The first node N1 may be a point where the second terminal of the second transistor T2 and the gate electrode of the first transistor T1 are connected to each other, and the second transistor T2 may transfer a data signal to the gate electrode of the first transistor T1.

The third transistor T3 may obtain a sensing signal through the sensing line SENj by electrically connecting the first transistor T1 to the sensing line SENj (for example, the j-th sensing line), and detect a characteristics of the sub-pixel SPX including a threshold voltage of the first transistor T1 by using the sensing signal. Information on the characteristic of the sub-pixel SPX may be used to convert image data so that a characteristic deviation between the sub-pixels SPX may be compensated. A second terminal of the third transistor T3 may be electrically connected to the second terminal of the first transistor T1, a first terminal of the third transistor T3 may be electrically connected to the sensing line SENj, and a gate electrode of the third transistor T3 may be electrically connected to the control line SCi (for example, the i-th control line). The first terminal may be a drain electrode, and the second terminal may be a source electrode.

The third transistor T3 may be an initialization transistor capable of initializing the second node N2, and may be turned on when a sensing control signal is supplied from the control line SCi to transfer a voltage of initialization power to the second node N2. Accordingly, the storage capacitor Cst electrically connected to the second node N2 may be initialized.

The storage capacitor Cst may include a lower electrode LE (or a first storage electrode) and an upper electrode UE (or a second storage electrode). The lower electrode LE may be electrically connected to the first node N1 and the upper electrode UE may be electrically connected to the second node N2. The storage capacitor Cst may charge a data voltage corresponding to the data signal supplied to the first node N1 during one frame period. Accordingly, the storage capacitor Cst may store a voltage corresponding to a difference between a voltage of the gate electrode of the first transistor T1 and a voltage of the second node N2.

In FIG. 4, an embodiment in which all of the first to third transistors T1 to T3 are N-type transistors is shown, but the disclosure is not limited thereto. In an alternative embodiment, for example, at least one selected from the first to third transistors T1 to T3 may be a P-type transistor. A structure of the pixel circuit PXC may be variously modified and implemented.

Hereinafter, for convenience of description, a width direction (or a horizontal direction) on a plane is indicated as the first direction DR1, a length direction (or a vertical direction) on the plane is indicated as the second direction DR2, and a vertical direction on a cross section is indicated as the third direction DR3.

FIG. 5A is a cross-sectional view illustrating an embodiment of the light emitting element of FIG. 4. FIG. 5B is a cross-sectional view illustrating an alternative embodiment of the light emitting element of FIG. 4.

Referring to FIG. 5A, an embodiment of the light emitting element LD may include the first pixel electrode AE, an organic light emitting unit EL, and the second pixel electrode CE that are sequentially stacked.

In an embodiment, the first pixel electrode AE may be patterned to correspond to the first to third sub-pixels (for example, the first to third sub-pixels SPX1 to SPX3).

In an embodiment, the organic light emitting unit EL may be provided on the first pixel electrode AE. The organic light emitting unit EL may have a multilayer thin film structure including a plurality of light generation layers. The organic light emitting unit EL may include a hole injection layer HIL, a hole transfer layer HTL, a light emitting layer EML, an electron transfer layer ETL, and an electron injection layer EIL that are sequentially stacked.

The hole injection layer HIL may be an organic layer disposed between the first pixel electrode AE and the hole transfer layer HTL to facilitates injection of a hole from the first pixel electrode AE into the light emitting layer EML. The hole transfer layer HTL may be disposed between the hole injection layer HIL and the first pixel electrode AE to receive the hole from the first pixel electrode AE and transfer the hole to the light emitting layer EML.

The electron injection layer EIL may be disposed between the electron transfer layer ETL and the second pixel electrode CE. The electron transfer layer ETL may be disposed on the light emitting layer EML to receive an electron from the second pixel electrode CE and transfer the electron to the light emitting layer EML.

The light emitting layer EML is an area in which light is generated by combination of the electron and the hole supplied from the first pixel electrode AE and the second pixel electrode CE. The light emitting layer EML may include an organic light emitting material such as a high molecular organic material or low molecular organic material that emits light of a predetermined color. In an embodiment, for example, the light emitting layer EML may include an organic material that emits blue light. However, the disclosure is not limited thereto. In an alternative embodiment, for example, the light emitting layer EML may include an organic material that emits red or green light, or may include an inorganic material or a quantum dot.

In an embodiment, the second pixel electrode CE may be integrally or commonly provided for the light emitting elements. The second pixel electrode CE may be disposed on the organic light emitting unit EL. The second pixel electrode CE may be integrally formed over the light emitting elements.

Referring to FIG. 5B, an alternative embodiment of the light emitting element LD may include the first pixel electrode AE, the organic light emitting unit EL, and the second pixel electrode CE.

The organic light emitting unit EL may include the plurality of light generation layers. In an embodiment, for example, the organic light emitting unit EL may include a first organic light emitting unit ELa, a charge generation layer CGL, and a second organic light emitting unit ELb. The first pixel electrode AE, the first organic light emitting unit ELa, the charge generation layer CGL, the second organic light emitting unit ELb, and the second pixel electrode CE may be sequentially stacked.

The first organic light emitting unit ELa may be provided in a structure in which the hole injection layer HIL, a first hole transfer layer HTLa, a first organic light emitting layer EMLa, and a first electron transfer layer ETLa are sequentially stacked. The second organic light emitting unit ELb may be provided in a structure in which a second hole transfer layer HTLb, a second organic light emitting layer EMLb, a second electron transfer layer ETLb, and the electron injection layer EIL are sequentially stacked.

In an embodiment, a buffer layer (not shown) may be disposed on the first organic light emitting layer EMLa and the second organic light emitting layer EMLb. The buffer layer may include an electron transferring compound.

The charge generation layer CGL may serve to supply a charge to the first organic light emitting unit ELa and the second organic light emitting unit ELb. In an embodiment, the charge generation layer CGL may be provided by including an n-type electron generation layer n-CGL for supplying the charge to the first organic light emitting unit ELa and a p-type charge generation layer p-CGL for supplying the hole to the second organic light emitting unit ELb. In such an embodiment, the n-type charge generation layer n-CGL may be provided by including a metal material as a dopant.

In an embodiment, as shown in FIG. 5B, the two organic light emitting units ELa and ELb of the light emitting element LD are stacked in the light emitting element LD, but the disclosure is not limited thereto. In an alternative embodiment, for example, three or four or more organic light emitting units may be stacked in the light emitting element LD.

FIG. 6 is a cross-sectional view illustrating an embodiment of the pixel including the light emitting element of FIG. 5A or 5B.

Referring to FIGS. 1 and 6, an embodiment of the display device DD may include the display area DA, and the display area DA may include first to third sub-pixel areas SPA1 to SPA3 and the non-emission area NEA. In an embodiment, for example, the first sub-pixel area SPA1 may be an area where the light of the first color of the first sub-pixel SPX1 is emitted. The second sub-pixel area SPA2 may be an area where the light of the second color of the second sub-pixel SPX2 is emitted. The third sub-pixel area SPA3 may be an area where the light of the third color of the third sub-pixel SPX3 is emitted. In an embodiment, for example, emission areas of the display area DA may correspond to the first to third sub-pixel areas SPA1 to SPA3. The first to third sub-pixel areas SPA1 to SPA3 and the non-emission area NEA may be defined by a bank BNK of the light-conversion layer LCL.

Referring to FIG. 6, an embodiment in which the first to third sub-pixel areas SPA1 to SPA3 are adjacent to each other in a direction crossing the third direction DR3 is shown, but the disclosure is not necessarily limited thereto.

In an embodiment, the pixel PXL may include the pixel-circuit layer PCL, the display element layer DPL, the encapsulation layer TFE, the light-conversion layer LCL, and the color-filter layer CFL sequentially disposed on the first substrate SUB1 in the third direction DR3.

Circuit elements (for example, the first to third transistors T1 to T3 of FIG. 4) and signal lines electrically connected to the circuit elements may be disposed in the pixel-circuit layer PCL. The pixel-circuit layer PCL may be disposed on the first substrate SUB1. The pixel-circuit layer PCL may include the first transistor T1, a buffer layer BFL, a gate insulating layer GI, an interlayer insulating layer ILD, a passivation layer PVX, and a via layer VIA. Although, for convenience of illustration, only one transistor T1 is shown in FIG. 6 as an example, the sub-pixel SPX may include a plurality of transistors and at least one capacitor for driving the light emitting element LD.

The buffer layer BFL may be disposed on the first substrate SUB1. The buffer layer BFL may effectively prevent an impurity from being diffused from an outside. The buffer layer BFL may effectively prevent the impurity from being diffused into the first transistor T1 provided on the first substrate SUB1 and improve flatness of the first substrate SUB1. The buffer layer BFL may be provided as (or defined by) a single layer or may be provided as multiple layers. The buffer layer BFL may be an inorganic insulating layer including an inorganic material. The inorganic insulating layer may include, for example, at least one selected from metal oxides such as silicon nitride (SiNₓ), silicon oxide (SiOₓ), silicon oxynitride (SiON), and aluminum oxide (AlOₓ). In an embodiment where the buffer layer BFL is provided as multiple layers, each layer may include or be formed of a same material as each other or different materials from each other. The buffer layer BFL may be omitted in some embodiments.

The first transistor T1 may include a semiconductor pattern SCP, a gate electrode GE, a first terminal TE1, and a second terminal TE2. The first terminal TE1 may be one of a source electrode and a drain electrode, and the second terminal TE2 may be the other thereof. In an embodiment, for example, the first terminal TE1 may be the drain electrode, and the second terminal TE2 may be the source electrode.

The semiconductor pattern SCP may be provided and/or formed on the buffer layer BFL. The semiconductor pattern SCP may include a first area contacting the first terminal TE1, a second area contacting the second terminal TE2, and a channel area between the first area and the second area. The channel area may overlap the gate electrode GE of the first transistor T1. The semiconductor pattern SCP may be a semiconductor pattern including or formed of amorphous silicon, polysilicon, low-temperature polysilicon, an oxide semiconductor, or an organic semiconductor. The channel area may be, for example, a semiconductor pattern that is not doped with an impurity, and may be an intrinsic semiconductor. The first area and the second area may be a semiconductor pattern doped with an impurity. In an embodiment, for example, the first terminal TE1 may be electrically connected to the light emitting element LD through connection electrodes CNE1 and CNE2.

The gate insulating layer GI may be provided and/or formed on the semiconductor pattern SCP. The gate insulating layer GI may be an inorganic insulating layer including an inorganic material. The gate insulating layer GI may include a same material as the buffer layer BFL or may include one or more materials selected from materials exemplified as a configuration material of the buffer layer BFL. In an embodiment, for example, the gate insulating layer GI may be provided as an organic insulating layer including an organic material. The gate insulating layer GI may be provided as a single layer, or may be provided as multiple layers of at least double or more layers.

The gate electrode GE may be provided and/or formed on the gate insulating layer GI to correspond to the channel area of the semiconductor pattern SCP. The gate electrode GE may be provided on the gate insulating layer GI and overlap the channel area of the semiconductor pattern SCP. The gate electrode GE may be formed in (provided as or defined by) a single layer including at least one material selected from copper (Cu), molybdenum (Mo), tungsten (W), aluminum neodymium (AlNd), titanium (Ti), aluminum (Al), silver (Ag), and an alloy thereof alone or a mixture thereof, or may be formed in a double layer or multilayer structure of a molybdenum (Mo), titanium (Ti), copper (Cu), aluminum (Al), or silver (Ag), which is a low-resistance material, to reduce a line resistance.

The interlayer insulating layer ILD may be provided and/or formed on the gate electrode GE. The first connection electrode CNE1 may be disposed on the interlayer insulating layer ILD. The first connection electrode CNE1 may be electrically connected to the first terminal TE1 through a contact hole (not shown) defined or formed through the gate insulating layer GI and the interlayer insulating layer ILD.

The passivation layer PVX may be provided and/or formed on the first connection electrode CNE1. The second connection electrode CNE2 may be disposed on the passivation layer PVX. The second connection electrode CNE2 may be electrically connected to the first connection electrode CNE1 through a contact hole (not shown) defined or formed through the passivation layer PVX.

The passivation layer PVX may be provided in a form including an inorganic insulating layer disposed on an organic insulating layer or an organic insulating layer disposed on an inorganic insulating layer. The inorganic insulating layer may include, for example, at least one selected from metal oxides such as silicon oxide (SiOₓ), silicon nitride (SiNₓ), silicon oxynitride (SiOₓN_{y}), and aluminum oxide (AlOₓ). The organic insulating layer may include, for example, at least one selected from acrylic resin (polyacrylate resin), epoxy resin, phenol resin, polyamide resin, polyimide resin, unsaturated polyesters resin, poly-phenylen ether resin, poly-phenylene sulfide resin, and benzocyclobutene resin.

The via layer VIA may be provided and/or formed entirely on the passivation layer PVX. The via layer VIA may be an inorganic insulating layer including an inorganic material or an organic insulating layer including an organic material.

The display element layer DPL may be disposed on the via layer VIA. The display element layer DPL may include the light emitting element LD and a pixel defining layer PDL. The light emitting element LD and the pixel defining layer PDL may be provided and/or formed on the via layer VIA. The light emitting elements LD may include a first light emitting element LD1 disposed in the first sub-pixel area SPA1, a second light emitting element LD2 disposed in the second sub-pixel area SPA2, and a third light emitting element LD3 disposed in third sub-pixel area SPA3.

Each of the light emitting element LD may include the first pixel electrode AE, the light emitting layer EML, and the second pixel electrode CE. The light emitting element LD may be electrically connected to a pixel circuit (for example, the pixel circuit PXC of FIG. 2) of a corresponding pixel.

The first pixel electrode AE may be provided and/or formed on the via layer VIA of the corresponding pixel. The first pixel electrode AE may be an anode electrode of the light emitting element LD. The first pixel electrode AE may be electrically connected to the first terminal TE1 through a corresponding contact portion (not shown). In an embodiment, for example, the first pixel electrode AE may include anode electrodes corresponding to the first to third sub-pixel areas SPA1 to SPA3. The first pixel electrode AE may be patterned to correspond to the first to third sub-pixel areas SPA1 to SPA3.

Each first pixel electrode AE may include or be formed of a conductive material (or substance). The conductive material may include an opaque metal. The opaque metal may include, for example, a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof. However, a material of each of first pixel electrode AE is not limited to the above-described embodiment. According to an embodiment, the first pixel electrode AE may include a transparent conductive material (or substance). The transparent conductive material (or substance) may include a conductive oxide such as indium tin oxide (ITO), indium zinc oxide (IZO), zinc oxide (ZnOx), indium gallium zinc oxide (IGZO), indium tin zinc oxide (ITZO), a conductive polymer such as poly (3,4-ethylenedioxythiophene) (PEDOT), or the like. In an embodiment where the first pixel electrode AE includes the transparent conductive material (or substance) and further include a separate conductive layer including or formed of an opaque metal for reflecting light emitted from the light emitting layer EML in an image display direction of the display device (for example, the display device DD of FIG. 1) (or toward the encapsulation layer TFE).

The pixel defining layer PDL may define (or partition) an area where the organic light emitting unit EL is disposed. The pixel defining layer PDL may be an organic insulating layer including or formed of an organic material. In an embodiment, the pixel defining layer PDL may include a light absorbing material or may be coated with a light absorbing material to absorb light introduced from the outside. In an embodiment, for example, the pixel defining layer PDL may include a carbon-based black pigment. However, the disclosure is not limited thereto.

The pixel defining layer PDL may be partially opened to with an opening (not shown, or a second opening) defined therethrough to expose one area of the first pixel electrode AE, and may protrude in a third direction DR3 from the via layer VIA along a circumference of the emission area EMA. The pixel defining layer PDL may be disposed on the via layer VIA to define an area where the organic light emitting unit EL is disposed on the first pixel electrode AE and accommodated. The organic light emitting unit EL may be disposed on the first pixel electrode AE exposed by the opening of the pixel defining layer PDL.

The organic light emitting unit EL may have a multilayer thin film structure including a light generation layer that generates light. The organic light emitting unit EL may emit one of red light, green light, and blue light, but is not limited thereto. In an embodiment, for example, the organic light emitting unit EL may include a white light emitting layer that emits white light. An internal design of the organic light emitting unit EL may also vary according to a color of light to be implemented.

The second pixel electrode CE may be disposed on the organic light emitting unit EL and the pixel defining layer PDL. The second pixel electrode CE may be provided in a plate shape over the entire area of the display area DA.

The second pixel electrode CE may be a thin film metal layer having a thickness sufficient to transmit the light emitted from the organic light emitting unit EL. The second pixel electrode CE may include or be formed of a metal material or a transparent conductive material to have a relatively thin thickness. The second pixel electrode CE may include at least one selected from various transparent conductive materials including ITO, IZO, ITZO, aluminum zinc oxide (AZO), gallium zinc oxide (GZO), zinc tin oxide (ZTO), or gallium tin oxide (GTO), and may be implemented as substantially transparent or translucent to satisfy a predetermined light transmittance. Accordingly, light emitted from the organic light emitting unit EL positioned under the second pixel electrode CE may pass through the second pixel electrode CE and may be emitted in an upper direction of the encapsulation layer TFE.

The encapsulation layer TFE may be entirely provided and/or formed on the second pixel electrode CE. The encapsulation layer TFE may include first to third layers EN1 to EN3 sequentially positioned on the second pixel electrode CE. The first layer EN1 and the third layer EN3 may be an inorganic layer including an inorganic material, and the second layer EN2 may be an organic layer including an organic material. The first layer EN1 and the third layer EN3 may protect the sub-pixel SPX from moisture and oxygen. The second layer EN2 may protect the sub-pixel SPX from a foreign substance such as a dust particle.

The light-conversion layer LCL may be disposed on the encapsulation layer TFE. In an embodiment, for example, the light-conversion layer LCL may be disposed on the third layer EN3 of the encapsulation layer TFE. The light-conversion layer LCL may include the bank BNK, a first capping layer CAP1, the color conversion layer CCL, and the low refractive layer LRL.

The bank BNK may be disposed on the encapsulation layer TFE. The bank BNK may be disposed between the first to third sub-pixel areas SPA1 to SPA3 (or the first to third sub-pixels SPX1 to SPX3 in FIG. 1) or at a boundary of the first to third sub-pixel areas SPA1 to SPA3 (or the first to third sub-pixels SPX1 to SPX3 of FIG. 1), and may define an opening (or a first opening) overlapping each of the first to third sub-pixel areas SPA1 to SPA3. In an embodiment, for example, a desired type and/or amount of the color conversion layer CCL may be supplied to a space partitioned by the opening defined or formed through the bank BNK.

The bank BNK may define the first to third sub-pixel areas SPA1 to SPA3 and the non-emission area NEA. The first to third sub-pixel areas SPA1 to SPA3 may be areas corresponding to the opening (or the first opening) of the bank BNK, and the non-emission area NEA may be an area corresponding to the bank BNK.

In an embodiment, the non-emission area NEA may be an area corresponding to an area where the bank BNK is disposed. The bank BNK may surround the first to third sub-pixel areas SPA1 to SPA3 in a plan view.

The bank BNK may include an organic material such as acrylates resin, epoxy resin, phenolic resin, polyamides resin, polyimides resin, polyesters resin, polyphenylenesulfides resin, or benzocyclobutene (BCB). However, the disclosure is not necessarily limited thereto, and the bank BNK may include at least one selected from various types of inorganic materials such as silicon oxide (SiOx), silicon nitride (SiNx), silicon oxynitride (SiOxNy), aluminum nitride (AlNx), aluminum oxide (AlOx), zirconium oxide (ZrOx), hafnium oxide (HfOx), or titanium oxide (TiOx).

The bank BNK may include at least one light blocking and/or reflective material. Accordingly, light leakage between adjacent sub-pixels may be effectively prevented. In an embodiment, for example, the bank BNK may include black pigment, but is not necessarily limited thereto.

The color conversion layer CCL may be accommodated in the opening of the bank BNK and may be disposed in an area corresponding to (or overlapping) the first to third sub-pixel areas SPA1 to SPA3. The color conversion layer CCL may include first to third color conversion layers CCL1 to CCL3 corresponding to the respective first to third sub-pixel areas SPA1 to SPA3. The first color conversion layer CCL1 may be disposed in the first sub-pixel area SPA1, the second color conversion layer CCL2 may be disposed in the second sub-pixel area SPA2, and the third color conversion layer CCL3 may be disposed in the third sub-pixel area SPA3. The color conversion layer CCL may include color conversion particles QD (or wavelength conversion particles). In an embodiment, for example, the color conversion layer CCL may include the color conversion particles QD that converts the light of the first color (or the first wavelength band) incident from the light emitting element LD into the light of the second color (the specific color, or the second wavelength band) different from the first color and emits the converted light of the second color.

In an embodiment, the first to third sub-pixel areas SPA1 to SPA3 may include first to third light emitting elements LD1 to LD3 that emit light of a same color. In an embodiment, for example, each of the first to third light emitting elements LD1 to LD3 may emit light of the third color (or blue). Since the first to third color conversion layers CCL1 to CCL3 including color conversion particles are disposed on the first to third sub-pixel areas SPA1 to SPA3, respectively, a full color of image may be displayed.

The first color conversion layer CCL1 may include first color conversion particles that convert the light of the third color emitted from the first light emitting element LD1 into the light of the first color (or the red light). In an embodiment, for example, the first color conversion layer CCL1 may include a plurality of quantum dot particles QD dispersed in a predetermined matrix material such as a base resin. The quantum dot particles QD of the first color conversion layer CCL1 may absorb the blue light and emit the red light by shifting a wavelength according to an energy transition.

The second color conversion layer CCL2 may include second color conversion particles that convert the third color light emitted from the second light emitting element LD2 into the light of the second color (or the green light). In an embodiment, for example, the second color conversion layer CCL2 may include a plurality of quantum dot particles QD dispersed in a predetermined matrix material such as a base resin. The quantum dot particles QD of the second color conversion layer CCL2 may absorb the blue light and emit the green light by shifting a wavelength according to an energy transition.

The third color conversion layer CCL3 may be provided to efficiently use the light of the third color (or blue) emitted from the third light emitting element LD3. In an embodiment, for example, where the third light emitting element LD3 is a blue light emitting element that emits blue light and the third sub-pixel area SPA3 is a blue sub-pixel area, the third color conversion layer CCL3 may include at least one type of scattering body SCT to efficiently use (or to improve light emission efficiency of) the light emitted from the third light emitting element LD3.

The first capping layer CAP1 may be entirely disposed on a surface of the bank BNK and the color conversion layer CCL. The first capping layer CAP1 may effectively prevent penetration of moisture or a foreign substance into the color conversion layer CCL. The first capping layer CAP1 may include an inorganic material. In an embodiment, the low refractive layer LRL may be disposed on the first capping layer CAP1. The low refractive layer LRL may control a path of light emitted from a lower portion of the color conversion layer CCL (or the display element layer DPL). In an embodiment, for example, the low refractive layer LRL may change a path of obliquely incident light into a direction perpendicular to a second planarization layer OC2. The low refractive layer LRL may include a polymer material and a silica-based material.

In an embodiment, a second capping layer CAP2 (or a base layer) may be disposed on the low refractive layer LRL. The second capping layer CAP2 may effectively prevent penetration of moisture or a foreign substance into the low refractive layer LRL. The second capping layer CAP2 may include an inorganic material.

In an embodiment, the color-filter layer CFL may be disposed on the light-conversion layer LCL. In an embodiment, for example, the color-filter layer CFL may be disposed on the second capping layer CAP2. The color-filter layer CFL may include color filters CF, the first planarization layer OC1, and the second planarization layer OC2. The color filters CF may include the first to third color filters CF1 to CF3 corresponding to the respective first to third sub-pixel areas SPA1 to SPA3.

In an embodiment, the first color filter CF1, the second color filter CF2, and the third color filter CF3 may be a red color filter, a green color filter, and a blue color filter, respectively, but are not necessarily limited thereto.

In an embodiment, the first color filter CF1 may be disposed on the second capping layer CAP2 in correspondence with the first sub-pixel area SPA1, and may selectively transmit light emitted from the first light emitting element LD1 and the first color conversion layer CCL1. In an embodiment, for example, the first color filter CF1 may overlap the first color conversion layer CCL1 in the third direction DR3 (or in a plan view). The first color filter CF1 may include a color material that selectively transmits the light of the first color (or red). In an embodiment, for example, where the first sub-pixel area SPA1 is a red sub-pixel area, the first color filter CF1 may include a red color filter material.

In an embodiment, the second color filter CF2 may be disposed on the second capping layer CAP2 in correspondence with the second sub-pixel area SPA2, and may selectively transmit light emitted from the second light emitting element LD2 and the second color conversion layer CCL2. In an embodiment, for example, the second color filter CF2 may overlap the second color conversion layer CCL2 in the third direction DR3. The second color filter CF2 may include a color filter material that selectively transmits the light of the second color (or green). In an embodiment, for example, where the second sub-pixel area SPA2 is a green sub-pixel area, the second color filter CF2 may include a green color filter material.

In an embodiment, the first planarization layer OC1 may be disposed on the first and second color filters CF1 and CF2. The first planarization layer OC1 may cover the first and second color filters CF1 and CF2. The first planarization layer OC1 is not particularly limited as long as the first planarization layer OC1 is a material having high planarization characteristic and light transmittance, but the first planarization layer OC1 may include an organic material or an inorganic material.

In an embodiment, the first planarization layer OC1 may be disposed in an area corresponding to the third sub-pixel area SPA3 on the second capping layer CAP2.

In an embodiment, the third color filter CF3 may be disposed on the first planarization layer OC1 in correspondence with the third sub-pixel area SPA3, and may selectively transmit light emitted from the third light emitting element LD3 and the third color conversion layer CCL3. In an embodiment, for example, the third color filter CF3 may overlap the third color conversion layer CCL3 in the third direction DR3. The third color filter CF3 may include a color filter material that selectively transmits the light of the third color (or blue). In an embodiment, for example, when the third sub-pixel area SPA3 is a blue sub-pixel area, the third color filter CF3 may include a blue color filter material.

In an embodiment, the second color filter CF2, the first color filter CF1, and the third color filter CF3 may be sequentially disposed in the third direction DR3. That is, after the second color filter CF2 is disposed, the first color filter CF1 may be disposed to cover the second color filter CF2 in the non-emission area NEA.

In an embodiment, the first and second color filters CF1 and CF2 may be disposed on the second capping layer CAP2. The first color filter CF1 may be disposed in an area corresponding to the first sub-pixel area SPA1, and may extend from the first sub-pixel area SPA1 to at least one area of the non-emission area NEA surrounding the first sub-pixel area SPA1. The second color filter CF2 may be disposed in an area corresponding to the second sub-pixel area SPA2, and may extend from the second sub-pixel area SPA2 to at least one area of the non-emission area NEA surrounding the second sub-pixel area SPA2. In an embodiment, for example, the first color filter CF1 extending to the non-emission area NEA may cover the second color filter CF2 extending to the non-emission area NEA.

In an embodiment, the third color filter CF3 may be disposed in an area corresponding to the third sub-pixel area SPA3 on the first planarization layer OC1, and may extend from the third sub-pixel area SPA3 to the non-emission area NEA surrounding the third sub-pixel area SPA3. In an embodiment, for example, the third color filter CF3 may be disposed in a layer different from a layer in which the first and second color filters CF1 and CF2 are disposed. In an embodiment, for example, the third color filter CF3 may not contact the first and second color filters CF1 and CF2.

In an embodiment, the third color filter CF3 may be disposed in an area corresponding to the non-emission area NEA surrounding the first and second sub-pixel areas SPA1 and SPA2 on the first planarization layer OC1.

In an embodiment, the third color filter CF3 may have a uniform thickness over the non-emission area NEA and the third sub-pixel area SPA3.

In an embodiment, the third color filter CF3 may be disposed on the flat first planarization layer OC1 to maintain flatness throughout the third sub-pixel area SPA3 and the non-emission area NEA surrounding the third sub-pixel area SPA3. In addition, the third color filter CF3 may have a predetermined thickness on the first planarization layer OC1. The third color filter CF3 may have a constant thickness in the third sub-pixel area SPA3 and the non-emission area NEA. However, the disclosure is not limited thereto, and a thickness of the third color filter CF3 disposed in the third sub-pixel area SPA3 may be thicker than a thickness of the third color filter CF3 disposed in the non-emission area NEA. In an embodiment, for example, the thickness of the third color filter CF3 may be determined to be equal to or greater than a predetermined thickness according to a process condition.

In an embodiment, the third color filter CF3 may overlap at least one selected from the first color filter CF1 and the second color filter CF2 in the non-emission area NEA.

In an embodiment, the second planarization layer OC2 may be disposed on the first planarization layer OC1 and may cover the third color filter CF3. The second planarization layer OC2 is not particularly limited as long as the second planarization layer OC2 includes a material having high planarization characteristic and light transmittance. In an embodiment, for example, the second planarization layer OC2 may include an organic material or an inorganic material.

In an embodiment, the second planarization layer OC2 may protect and support the first to third color filters CF1 to CF3 disposed under the second planarization layer OC2.

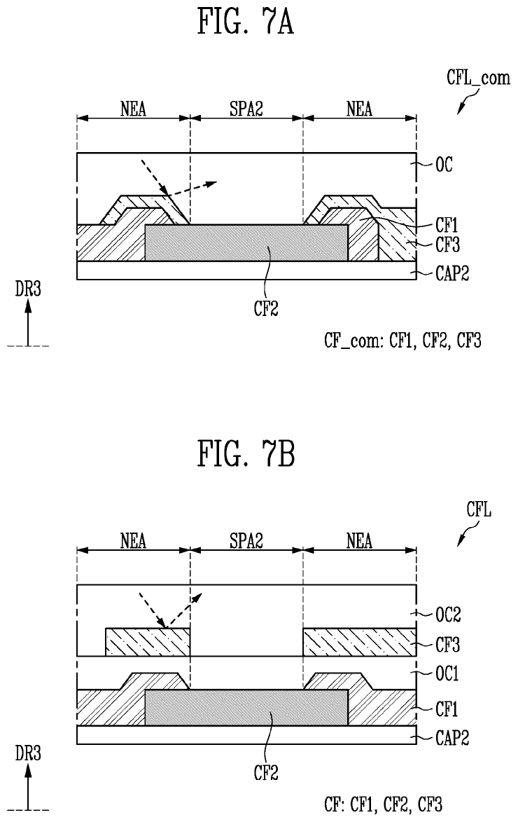

FIG. 7A is a cross-sectional view illustrating a comparative example of a color-filter layer of sub-pixels included in a pixel. FIG. 7B is a cross-sectional view illustrating an embodiment of the color-filter layer of the sub-pixels included in the pixel of FIG. 6.

Hereinafter, with reference to FIGS. 7A and 7B, the disclosure is described based on a portion of the comparative example of the color-filter layer CFL_com or a portion of an embodiment of the color-filter layer CFL corresponding to the second sub-pixel area SPA2 and the non-emission area NEA surrounding the second sub-pixel area SPA2.

Referring to FIG. 7A, the comparative example of the color-filter layer CFL_com may include first to third color-filter layers CF1 to CF3 and a planarization layer OC. The first to third color-filter layers CF1 to CF3 of the comparative example of the color-filter layer CFL_com may be sequentially disposed on the planarization layer OC in the third direction DR3. In the non-emission area NEA, the second color filter CF2, the first color filter CF1, and the third color filter CF3 may be sequentially disposed.

The second color filter CF2 of the comparative example of the color-filter layer CFL_com may be disposed in an area corresponding to the second sub-pixel area SPA2 on the second capping layer CAP2, and may extend to at least one area of the non-emission area NEA surrounding the second sub-pixel area SPA2.

The first color filter CF1 of the comparative example of the color-filter layer CFL_com may be disposed in an area corresponding to the first sub-pixel area on the second capping layer CAP2, may extend to the non-emission area NEA, and may cover at least a portion of the second color filter CF2 disposed in the non-emission area NEA.

In the comparative example of the color-filter layer CFL_com, the third color filter CF3 may be disposed on the outermost side of the non-emission area NEA, may be directly disposed on the first color filter CF1, and may cover the second color filter CF2. In the comparative example of the color-filter layer CFL_com, the first color filter CF1 covers the second color filter CF2 disposed in the non-emission area NEA, such that the first color filter CF1 may have a curved or inclined portion according to a surface profile of the second color filter CF2. In addition, as the third color filter CF3 is disposed on the first color filter CF1 covering the second color filter CF2, the third color filter CF3 may have a curved or angled portion corresponding to a curved or angled area of the first color filter CF1.

Referring to FIG. 7A, when external light is incident to the non-emission area NEA of the comparative example of the color-filter layer CFL_com, since a curved or angled portion is formed on a surface of the non-emission area NEA, the incident light may be diffused in various directions and reflected (hereinafter referred to as diffuse reflection), may be recognized by a user using the display device, and thus may reduce display quality. In the comparative example of the color-filter layer CFL_com, since a thickness of the third color filter CF3 disposed in the outermost area in the non-emission area NEA is thinner than that of the other color filters, when the external light is incident to the non-emission area NEA, portion of light of a third color (or blue) of the incident light may not be sufficiently absorbed by the third color filter CF3 and may be reflected.

Referring to FIG. 7B, the color-filter layer CFL according to an embodiment of the disclosure may include the first to third color-filter layers CF1 to CF3 and the first and second planarization layers OC1 and OC2. The first and second color filters CF1 and CF2 may be disposed on the second capping layer CAP2, and the third color filter CF3 may be disposed on the first planarization layer OC1.

The first color filter CF1 may cover the second color filter CF2 extending to the non-emission area NEA. In the non-emission area NEA, the third color filter CF3 may be disposed on the first planarization layer OC1 covering the first and second color filters CF1 and CF2. The third color filter CF3 may have a flat upper surface according to a surface profile of the first planarization layer OC1.

When external light is incident to the non-emission area NEA of the color-filter layer CFL, the external light is incident to an upper surface of the third color filter CF3 among the first to third color filters CF1 to CF3. The light incident to the third color filter CF3 may be reflected (hereinafter referred to as regular reflection) at a same angle as the incident angle, or most of the light of the third color (or blue) may be absorbed by the third color filter CF3.

As the display device according to an embodiment of the disclosure may include the third color filter CF3 having a flat surface with a predetermined constant thickness by disposing the third color filter CF3 on the first planarization layer OC1, the display device may minimize (or prevent) deterioration in visibility due to reflected light (or diffuse reflection) when external light is incident to the non-emission area NEA of the color-filter layer CFL.

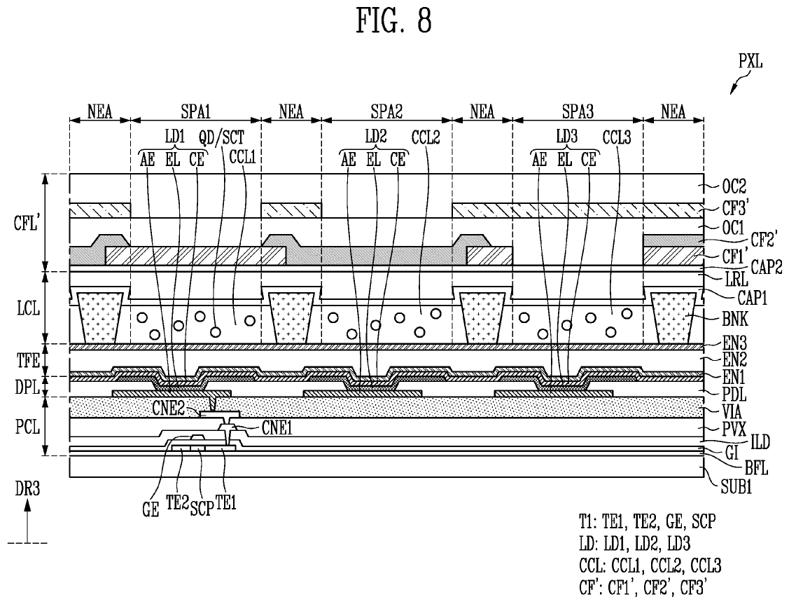

FIG. 8 is a cross-sectional view illustrating an alternative embodiment of the pixel including the light emitting element of FIG. 5A or 5B.

Hereinafter, for convenience of description, any repetitive detailed description of the same or like elements of the embodiment of FIG. 8 as those described above will be omitted, and a feature different from that of the above-described embodiment (for example, the embodiment of FIG. 6) will be mainly described.

Referring to FIG. 8, remaining configurations other than a color-filter layer CFL′ may be the same as or correspond to those described above with reference to FIG. 6.

Referring to FIG. 8, in an embodiment, the color-filter layer CFL′ may be disposed on the light-conversion layer LCL. The color-filter layer CFL′ may include color filters CF′, the first planarization layer OC1, and the second planarization layer OC2. The color filters CF′ may include first to third color filters CF1′ to CF3′ corresponding to the respective first to third sub-pixel areas SPA1 to SPA3.

In an embodiment, the first color filter CF1′, the second color filter CF2′, and the third color filter CF3′ may be sequentially formed in the third direction DR3. That is, after the first color filter CF1′ is disposed, the second color filter CF2′ may be disposed to cover the first color filter CF1′ in the non-emission area NEA.

In an embodiment, the first and second color filters CF1′ and CF2′ may be disposed on the second capping layer CAP2. The first color filter CF1′ may be disposed in an area corresponding to the first sub-pixel area SPA1, and may extend from the first sub-pixel area SPA1 to at least one area of the non-emission area NEA surrounding the first sub-pixel area SPA1. The second color filter CF2′ may be disposed in an area corresponding to the second sub-pixel area SPA2, and may extend from the second sub-pixel area SPA2 to at least one area of the non-emission area surrounding the second sub-pixel area SPA2. In an embodiment, for example, the second color filter CF2′ extending to the non-emission area NEA may cover the first color filter CF1′ extending to the non-emission area NEA.

In an embodiment, the first color filter CF1′ and the second color filter CF2′ may be sequentially disposed in the third direction DR3 on the second capping layer CAP2 in the non-emission area NEA surrounding the third sub-pixel area SPA3.

In an embodiment, the third color filter CF3′ may be disposed in an area corresponding to the third sub-pixel area SPA3 on the first planarization layer OC1, and may extend from the third sub-pixel area SPA3 to the non-emission area NEA surrounding the third sub-pixel area SPA3. In an embodiment, for example, the third color filter CF3′ may be disposed on a layer different from a layer in which the first and second color filters CF1′ and CF2′ are disposed. In an embodiment, for example, the third color filter CF3′ may not contact the first and second color filters CF1′ and CF2′.

In an embodiment, the third color filter CF3′ may be disposed in an area corresponding to the non-emission area NEA surrounding the first and second sub-pixel areas SPA and SPA2 on the first planarization layer OC1.

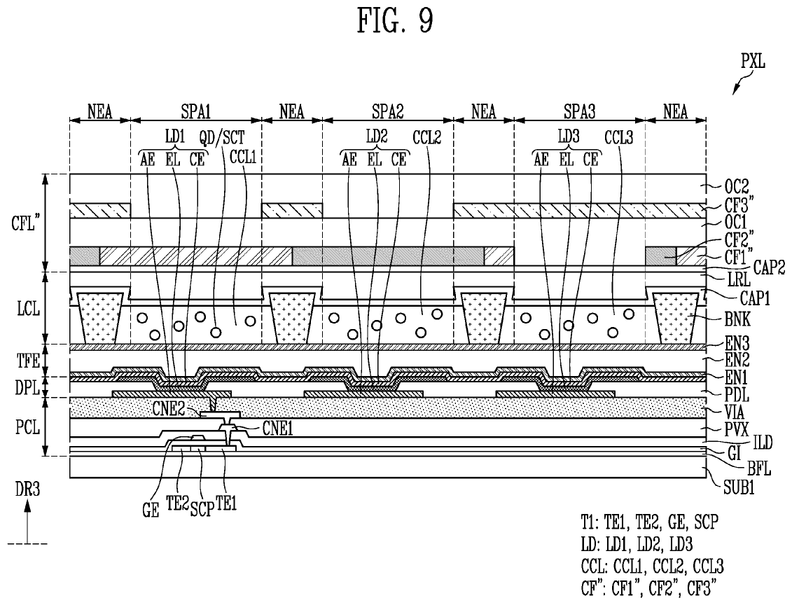

FIG. 9 is a cross-sectional view illustrating another alternative embodiment of the pixel including the light emitting element of FIG. 5A or 5B.

Hereinafter, for convenience of description, any repetitive detailed description of the same or like elements of the embodiment of FIG. 9 as those described above will be omitted, and a feature different from that of the above-described embodiment (for example, the embodiment of FIG. 6) will be mainly described

Referring to FIG. 9, remaining configurations other than a color-filter layer CFL″ may be the same as or correspond to those described above with reference to FIG. 6.

Referring to FIG. 9, in an embodiment, the color-filter layer CFL″ may be disposed on the light-conversion layer LCL. The color-filter layer CFL″ may include color filters CF″, the first planarization layer OC1, and the second planarization layer OC2. The color filters CF″ may include first to third color filters CF1″ to CF3″ corresponding to the respective first to third sub-pixel areas SPA1 to SPA3.

In an embodiment, the first and second color filters CF1″ and CF2″ may be disposed on the second capping layer CAP2. The first color filter CF1″ may be disposed in an area corresponding to the sub-pixel area SPA1, and may extend from the first sub-pixel area SPA1 to at least one area of the non-emission area NEA surrounding the first sub-pixel area SPA1. The second color filter CF2″ may be disposed in an area corresponding to the second sub-pixel area SPA2, and may extend from the second sub-pixel area SPA2 to at least one area of the non-emission area NEA surrounding the second sub-pixel area SPA2.

In an embodiment, the first color filter CF1″ and the second color filter CF2″ may be sequentially disposed in a direction crossing the third direction DR3. The first color filter CF1″ and the second color filter CF2″ extending to the non-emission area NEA may not overlap each other in a plan view.

In an embodiment, the third color filter CF3″ may overlap one of the first color filter CF1″ and the second color filter CF2″ in the non-emission area NEA.

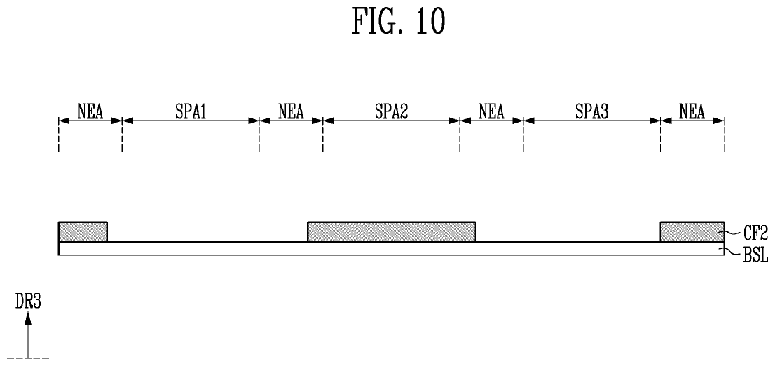

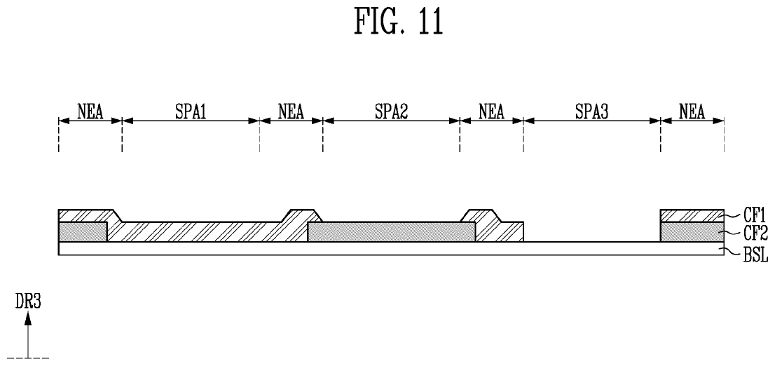

FIGS. 10 to 15 are cross-sectional views illustrating a method of manufacturing a display device according to embodiments of the disclosure.

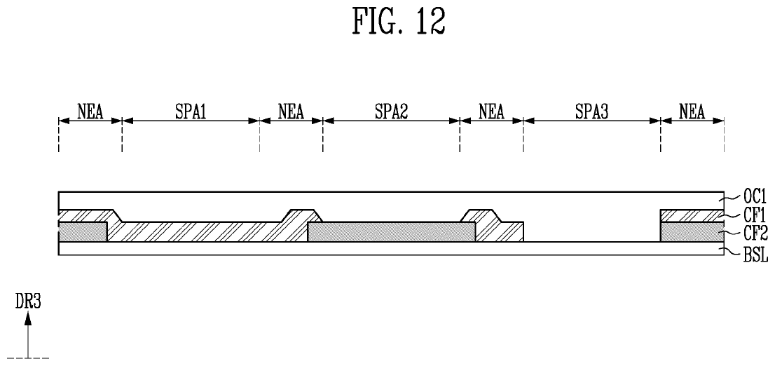

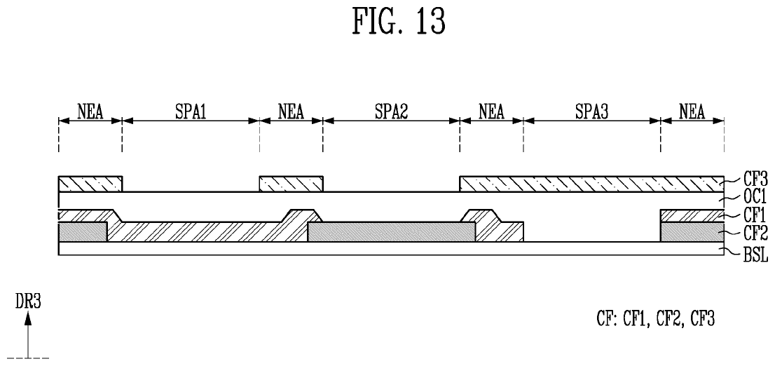

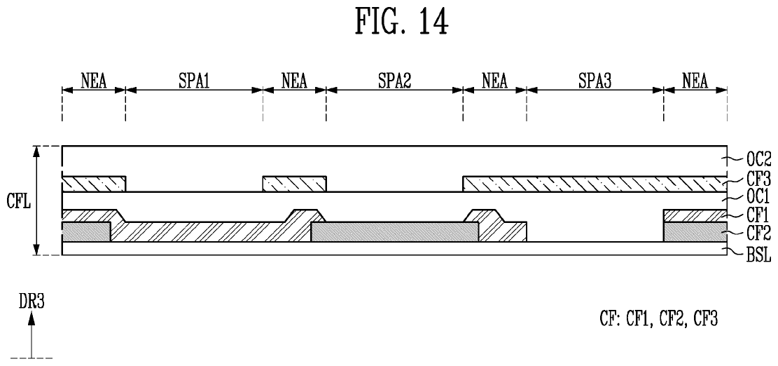

Referring to FIGS. 6 and 10 to 16, a method of manufacturing a display device according to embodiments of the disclosure may include forming the first substrate SUB1 on which the first to third sub-pixel areas SPA1 to SPA3 and the non-emission area NEA corresponding to a boundary of the first to third sub-pixel areas SPA1 to SPA3 are defined, forming the base layer (or the second capping layer CAP2) on the first substrate SUB1, forming the second color filter CF2 corresponding to the second sub-pixel area SPA2 on the base layer BSL (refer to FIG. 10), forming the first color filter CF1 corresponding to the first sub-pixel area SPA1 on the base layer BSL (refer to FIG. 11), forming the first planarization layer OC1 covering the first color filter CF1 and the second color filter CF2 (refer to FIG. 12), forming the third color filter CF3 corresponding to the third sub-pixel area SPA3 on the first planarization layer OC1 (refer to FIG. 13), and forming the second planarization layer OC2 covering the third color filter CF3 (refer to FIG. 14).

Hereinafter, an embodiment of a method of manufacturing the color-filter layer CFL disposed on the display element layer (for example, the display element layer DPL of FIG. 6) will be described with reference to FIGS. 10 to 15. The color-filter layer CFL may be formed on the display element layer DPL (or the light-conversion layer LCL).

Referring to FIG. 10, the second color filter CF2 may be formed on the base layer BSL corresponding to the second sub-pixel area SPA2. In an embodiment, for example, the first to third sub-pixel areas SPA1 to SPA3 and the non-emission area NEA corresponding to a boundary of the first to third sub-pixel areas SPA1 to SPA3 may be defined on the base layer BSL. The base layer BSL may correspond to the second capping layer CAP2 of FIG. 6. The base layer BSL may include an inorganic material.

In an embodiment, the second color filter CF2 may be formed in the second sub-pixel area SPA2 and the non-emission area NEA on the base layer BSL. In an embodiment, for example, the second color filter CF2 may extend from the second sub-pixel area SPA2 to the non-emission area NEA surrounding the second sub-pixel area SPA2.

Referring to FIG. 11, the first color filter CF1 may be formed on the base layer BSL corresponding to the first sub-pixel area SPA1 or to overlap the first sub-pixel area SPA1.

In an embodiment, the first sub-pixel area SPA1 may be formed adjacent to the second sub-pixel area SPA2. In an embodiment of example, the non-emission area NEA may be defined by an area corresponding to a boundary of the first sub-pixel area SPA1 and the second sub-pixel area SPA2.

In an embodiment, the first color filter CF1 may be formed in the first sub-pixel area SPA1 and the non-emission area NEA on the base layer BSL. In an embodiment, for example, the first color filter CF1 may extend from the first sub-pixel area SPA1 to the non-emission area NEA surrounding the first sub-pixel area SPA1. The first color filter CF1 extending to the non-emission area NEA may cover at least a portion of the second color filter CF2. In an embodiment, for example, the first color filter CF1 and the second color filter CF2 may at least partially overlap each other in the non-emission area NEA.

Referring to FIG. 12, the first planarization layer OC1 may be formed to cover the first and second color filters CF1 and CF2 on the base layer BSL. The first planarization layer OC1 may include or be formed of an organic material to planarize a lower step difference, but is not limited thereto and may include various types of inorganic materials. In an embodiment, for example, the first planarization layer OC1 may contact the base layer BSL corresponding to the third sub-pixel area SPA3.

Referring to FIG. 13, the third color filter CF3 may be formed on the first planarization layer OC1 corresponding to the third sub-pixel area SPA3.

In an embodiment, the third sub-pixel area SPA3 may be formed adjacent to the second sub-pixel area SPA2. In an embodiment, for example, the non-emission area NEA may be formed in an area corresponding to a boundary of the third sub-pixel area SPA3 and the second sub-pixel area SPA2.

In an embodiment, the third color filter CF3 may be formed in the third sub-pixel area SPA3 and the non-emission area NEA on the first planarization layer OC1. In an embodiment, for example, the third color filter CF3 may extend from the third sub-pixel area SPA3 to the non-emission area NEA surrounding the third sub-pixel area SPA3. In an embodiment, for example, the third color filter CF3 may extend to the non-emission area NEA surrounding the first and second color filters CF1 and CF2.

In an embodiment, the first planarization layer OC1 may include an inner surface contacting the first and second color filters CF1 and CF2 and an outer surface contacting the third color filter CF3. In an embodiment, for example, the inner surface of the first planarization layer OC1 may have a profile according to a surface shape of the first and second color filters CF1 and CF2, and the outer surface of the first planarization layer OC1 may have a flat surface.

In an embodiment, the third color filter CF3 may be formed on the outer surface of the first planarization layer OC1 and may have a constant thickness based on the outer surface of the first planarization layer OC1 throughout the third sub-pixel area SPA3 and the non-emission area NEA.

In an embodiment, the third color filter CF3 may be disposed on the first planarization layer OC1 different from the base layer BSL, which is a layer on which the first and second color filters CF1 and CF2 are disposed. When external light is incident toward the non-emission area NEA of the base layer BSL, the external light may be incident to the third color filter CF3 disposed in the non-emission area NEA.

In an embodiment, the upper surface of the third color filter CF3 to which the external light is incident has a flat upper surface according to a surface profile of the outer surface of the first planarization layer OC1, and accordingly, when the external light is incident, the external light may be regularly reflected or may be absorbed by the third color filter CF3.

Referring to FIG. 14, the second planarization layer OC2 may be formed to cover the third color filter CF3 on the first planarization layer OC1. The second planarization layer OC2 may be made of an organic material to planarize the lower step, but is not limited thereto and may include various types of inorganic materials. In an embodiment, for example, the second planarization layer OC2 may contact the first planarization layer OC1 corresponding to the first and second sub-pixel areas SPA1 and SPA2.

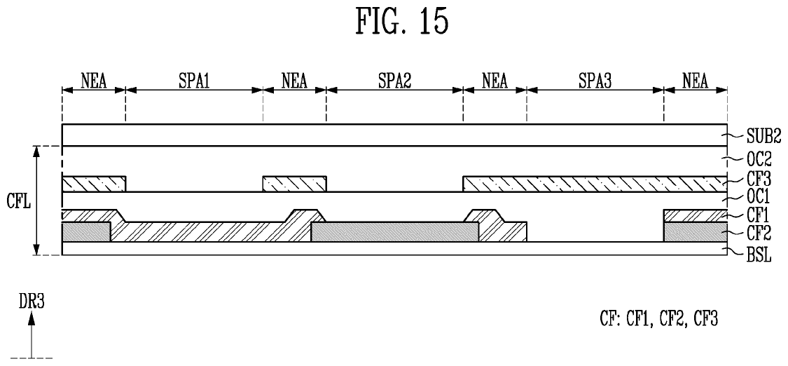

Referring to FIG. 15, a second substrate SUB2 may be formed on the second planarization layer OC2. The second substrate SUB2 may protect and/or support the color-filter layer CFL formed under the second substrate SUB2. In an embodiment, for example, the second substrate SUB2 may include a transparent insulating material to transmit light. The second substrate SUB2 may be a rigid substrate or a flexible substrate. The rigid substrate may be, for example, one of a glass substrate, a quartz substrate, a glass ceramic substrate, and a crystalline glass substrate.

In an alternative embodiment, the second substrate SUB2 may be omitted. In such an embodiment, the second planarization layer OC2 may protect and/or support the color filters CF1 to CF3 disposed under the second planarization layer OC2. In an embodiment, for example, the second planarization layer OC2 may include a transparent insulating material to transmit light.

According to an embodiment of the method of manufacturing the display device, the third color filter CF3 may be formed on the first planarization layer OC1 to have a flat surface and secure a predetermined thickness, and thus deterioration in visibility due to reflected light (or diffuse reflected light) when external light is incident to the non-emission area NEA of the color-filter layer CFL may be substantially reduced or effectively prevented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a first substrate, on which first to third sub-pixel areas spaced apart from each other and a non-emission area corresponding to a boundary of the first to third sub-pixel areas are defined;
a display element layer including a light emitting element disposed in each of the first to third sub-pixel areas on the first substrate; and
a color-filter layer disposed on the display element layer,
wherein the color-filter layer comprises:
a base layer;
a first color filter disposed on the base layer and corresponding to the first sub-pixel area;
a second color filter disposed on the base layer and corresponding to the second sub-pixel area;
a first planarization layer covering the first color filter and the second color filter;
a third color filter disposed on the first planarization layer and corresponding to the third sub-pixel area; and
a second planarization layer covering the third color filter.

2. The display device according to claim 1, wherein the first planarization layer directly contacts a portion of the base layer corresponding to the third sub-pixel area.

3. The display device according to claim 1, wherein the first and second color filters are disposed in a same layer as each other, and
the third color filter is disposed in a layer different from a layer in which the first and second color filters are disposed, with the first planarization layer interposed therebetween.

4. The display device according to claim 1, wherein a portion of the second color filter overlapping the non-emission area is at least partially covered by a portion of the first color filter overlapping the non-emission area.

5. The display device according to claim 1, wherein a portion of the second color filter overlapping the non-emission area covers at least a portion of the first color filter overlapping the non-emission area.

6. The display device according to claim 1, wherein a portion of each of the first to third color filters is disposed in the non-emission area, and
the portion of each of the first to third color filters disposed in the non-emission area are sequentially stacked in a third direction.

7. The display device according to claim 1, wherein a portion of the first color filter and a portion of the second color filter, each overlapping the non-emission area, overlap a portion of the third color filter disposed in the non-emission area in a plan view.

8. The display device according to claim 1, wherein the first to third color filters are disposed in the non-emission area, and
the first color filter and the second color filter disposed in the non-emission area do not overlap each other in a plan view.

9. The display device according to claim 1, wherein the third color filter has a constant thickness over the third sub-pixel area and the non-emission area.

10. The display device according to claim 1, further comprising:
an encapsulation layer disposed on the display element layer; and
a light-conversion layer disposed between the encapsulation layer and the color-filter layer.

11. The display device according to claim 10, wherein the light-conversion layer comprises:
a bank disposed in the boundary of the first to third sub-pixel areas and defining a first opening; and
a color conversion layer disposed in the first opening of the bank.

12. The display device according to claim 11, wherein the light-conversion layer further comprises:
a first capping layer covering the bank and the light-conversion layer; and
a low refractive layer disposed on the first capping layer.

13. The display device according to claim 1, wherein the display element layer comprises:
first pixel electrodes disposed in the first to third sub-pixel areas on the substrate;
a pixel defining layer disposed on the first pixel electrodes, wherein second openings are defined through the pixel defining layer to expose the first pixel electrodes;
an organic light emitting unit disposed on the first pixel electrodes; and
a second pixel electrode disposed on the organic light emitting unit.

14. The display device according to claim 1, wherein the third color filter does not contact the first and second color filters.

15. A method of manufacturing a display device, the method comprising:
preparing a first substrate on which first to third sub-pixel areas and a non-emission area corresponding to a boundary of the first to third sub-pixel areas are defined;
forming a base layer on the first substrate;
forming a second color filter corresponding to the second sub-pixel area on the base layer;
forming a first color filter corresponding to the first sub-pixel area on the base layer;
forming a first planarization layer covering the first color filter and the second color filter on the base layer;
forming a third color filter corresponding to the third sub-pixel area on the first planarization layer; and
forming a second planarization layer covering the third color filter on the first planarization layer.

16. The method according to claim 15, further comprising:
forming a display element layer including a light emitting element disposed in each of the first to third sub-pixel areas between the first substrate and the base layer.

17. The method according to claim 15, wherein the forming the first color filter comprises forming the first color filter to extend from the first sub-pixel area to the non-emission area, and
the forming the second color filter comprises forming the second color filter to extend from the second sub-pixel area to the non-emission area.

18. The method according to claim 17, wherein a portion of the first color filter overlapping the non-emission area covers a portion of the second color filter overlapping the non-emission area.

19. The method according to claim 17, wherein a portion of the second color filter overlapping the non-emission area covers a portion of the first color filter overlapping the non-emission area.

20. The method according to claim 15, wherein the forming the first planarization layer comprises filling the third sub-pixel area on the base layer.

21. The method according to claim 15, wherein the forming the third color filter comprises forming the third color filter at a constant thickness from the third sub-pixel area to the non-emission area.
